(19) United States
(12) Patent Application Publication
(10) Pub. No.: US 2013/0215309 A1
(43) Pub. Date: Aug. 22, 2013

(54) SOLID-STATE IMAGING DEVICE AND MANUFACTURING METHOD THEREOF, AND CAMERA SYSTEM

(71) Applicant: Sony Corporation, (US)

(72) Inventor: Masahiko Yukawa, Kanagawa (JP)

(73) Assignee: SONY CORPORATION, Tokyo (JP)

(21) Appl. No.: 13/755,848

(22) Filed: Jan. 31, 2013

(30) Foreign Application Priority Data
Feb. 21, 2012 (JP) 2012-035311

(51) Int. Cl. H01L 31/18; H04N 5/374; H01L 27/146

(52) U.S. Cl. CPC H01L 31/18; H01L 27/146; H04N 5/374
USPC 348/308; 250/208.1; 438/68

(57) ABSTRACT

There is provided a solid-state imaging device including a pixel part obtained by arranging a plurality of pixels performing photoelectric conversion, and a pixel signal readout part including a logic part and reading out a pixel signal from the pixel part, wherein the pixel part and the logic part are formed as a layered structure, wherein the layered structure includes a low hardness layer at least lower in hardness than another layer out of a plurality of layers, and wherein a dividing part different from the other layer is formed in a side portion of the low hardness layer.

### BACKGROUND

The present technology relates to a solid-state imaging device and a manufacturing method thereof, and a camera system which device is formed by dividing a wafer having a layered structure including a hard layer and a soft layer due to dicing into pieces.

Typically, an image capturing device is obtained by assembling individual packages, as modules, in which two chips of a CMOS image sensor (CIS) chip and an image processing chip are mounted, respectively. Or, there is also a case of each of the chips undergoing COB (Chip On Board) packaging.

In case of an image capturing device mounted in a mobile phone or the like, reduction in packaging area and miniaturization are expected recent years, and thus, SOC (System On Chip) technology for integrating the above-mentioned two chips into one chip is developed.

However, process for the integration into one chip in which process CIS process and hi-speed logic process are mixed expects increased steps and costs high, and in addition, is difficult to manage both analog characteristics and logic characteristics, this leading to the risk of deterioration of characteristics of the image capturing device. Therefore, a method for managing both miniaturization and improvement in characteristics due to a layered structure obtained by chip-level assembling of the above-mentioned two chips is proposed (see, Japanese Patent Laid-Open No. 2004-146816 and Japanese Patent Laid-Open No. 2008-085755).

Portions A and B of FIG. 1 illustrate a process flow of a solid-state imaging device with a layered structure.

As illustrated in portion A of FIG. 1, after wafers 1 and 2 prepared with processes most suitable for respective upper and lower first and second chips are pasted together, the rear face of the upper chip is polished and the thickness of the wafer of the upper chip is made thinner. Signal lines and power supply lines between the upper and lower chips are electrically joined through via holes (VIA) whose through holes are filled with metal. Then, as illustrated in portion B of FIG. 1, after performing processing to obtain color filters and microlenses on the first chip (upper chip) side, chips are cut out by dicing.

FIG. 2 is a diagram for explaining a typical method of cutting out chips by dicing. Moreover, CW in FIG. 2 denotes a cutting width with a blade.

The wafer with the layered structure in which chips CP are arranged in an array shape is cut with a blade along scribe lines SCL indicating positions for cutting between the chips, and is divided into the individual chips CP.

In FIG. 2, a simplified cross section taken along the scribe line SCL which is the position for cutting is partially enlarged and illustrated. In the layered structure in FIG. 2, a silicon (Si) layer 11 and a nitride film (for example, SiN film) 12 are layered to form the CIS-side wafer 1. In practice, sensors and the like are formed on the other face side opposite to the face of the Si layer 11 on which the SiN film is formed. A silicon layer 21, an oxide film 22, a wiring (for example, copper) layer 23, an SiO₂ layer 24 and an SiO₂ layer 25 are layered to form the logic-side wafer 2. Furthermore, in the simplified structure in FIG. 2, the SiN film 12 of the CIS-side wafer 1 and the SiO₂ layer 25 of the logic-side wafer 2 are pasted together.

In addition, the SiN film 12 is a relatively hard film. Moreover, to the wiring layer 23, a low dielectric constant film is applied in order to ensure a low resistance for the reason that such low resistance is not easy to realize due to wirings being thinner while more refinement of the process is being pursued and the like. This wiring layer 23 including the low dielectric constant film is formed of brittle material which is softer in hardness than the other layers, especially, the SiN film.

Dicing includes blade dicing after laser ablation, stealth dicing and the like other than the above-mentioned blade dicing solely with a blade.

### SUMMARY

However, there are following disadvantages in the above-mentioned blade dicing solely with a blade. FIGS. 3(A) and 3(B) are diagrams for explaining the problem in the blade dicing solely with a blade.

As illustrated in FIGS. 3(A) and 3(B), the presence of a hard film such as the nitride film 12 and the wiring layer 23 with low dielectric constant (Low-k) in the scribe line SCL causes significant deterioration of cutting quality due to stress propagating in the hard film (layer). As a result, cracks CRK proceed into the circuit portion of the chip CP, this leading to the risk of damaging device functions. Moreover, moisture happening to permeate through the crack portions in use of the device in the environment of the market, leads to the risk of a corrosion factor of wirings of the device circuitry.

Moreover, the stealth dicing gives rise to dusts, and the dusts again stick to the device surface. Thus, this is difficult to be applied to image sensor devices.

Moreover, since the blade dicing after laser ablation is a technique of concentrating laser on the chip surface, this expecting steps of applying and peeling a protective film. Furthermore, dusts arising from reforming with laser again stick to the device surface. Thus, this technique is difficult to be applied to image sensor devices.

It is desirable to provide a solid-state imaging device and a manufacturing method thereof, and a camera system capable of preventing, while suppressing occurrence of dusts, occurrence of cracks even in blade dicing and improving cutting quality and yield of dicing.

According to a first embodiment of the present disclosure, there is provided a solid-state imaging device including a pixel part obtained by arranging a plurality of pixels performing photoelectric conversion, and a pixel signal readout part including a logic part and reading out a pixel signal from the pixel part. The pixel part and the logic part are formed as a layered structure. The layered structure includes a low hardness layer at least lower in hardness than another layer out of a plurality of layers. And a dividing part different from the other layer is formed in a side portion of the low hardness layer.

According to a second embodiment of the present disclosure, there is provided a manufacturing method of a solid-state imaging device including in performing blade dicing along a scribe line between chips with respect to a wafer obtained by arranging, in an array shape, the chips each having a layered structure which is obtained by layering a pixel part obtained by arranging a plurality of pixels performing photoelectric conversion and a logic part and includes a low hardness layer at least lower in hardness than another layer out of a plurality of layers, before performing the blade dicing, forming a dividing part, for dividing, having a predetermined width only inside at least within a boundary region between the chip and the scribe line in the low hardness layer, and after that, performing positioning such that a cut end face of a blade is located within the width of the dividing part to perform the blade dicing.

According to a third embodiment of the present disclosure, there is provided a camera system including a solid-state imaging device, and an optical part imaging a subject image in the solid-state imaging device. The solid-state imaging device includes, a pixel part obtained by arranging a plurality of pixels performing photoelectric conversion, and a pixel signal readout part including a logic part and reading out a pixel signal from the pixel part. The pixel part and the logic part are formed as a layered structure. The layered structure includes a low hardness layer at least lower in hardness than another layer out of a plurality of layers. A dividing part different from the other layer is formed in a side portion of the low hardness layer.

According to the present technology, while suppressing occurrence of dusts, occurrence of cracks can be prevented even in blade dicing and cutting quality and yield of dicing can be improved.

### BRIEF DESCRIPTION OF THE DRAWINGS

FIG. 1 is a diagram illustrating a process flow of a solid-state imaging device with a layered structure;

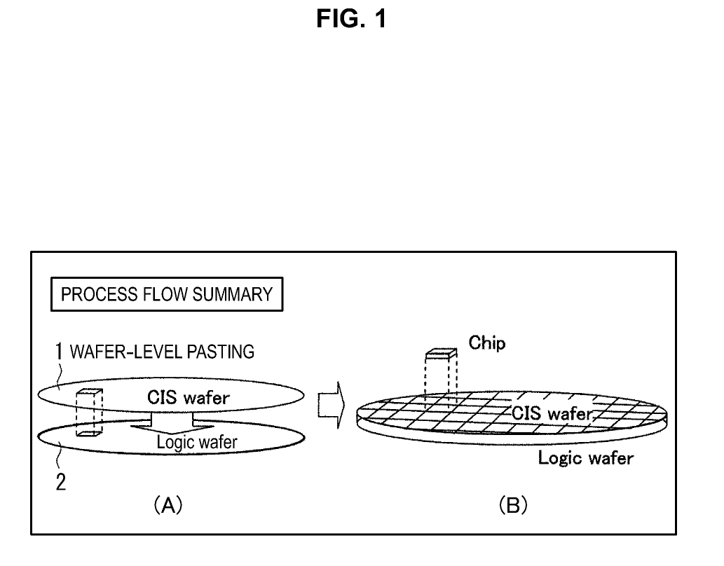

FIG. 2 is a diagram for explaining a typical method of cutting out chips by dicing;

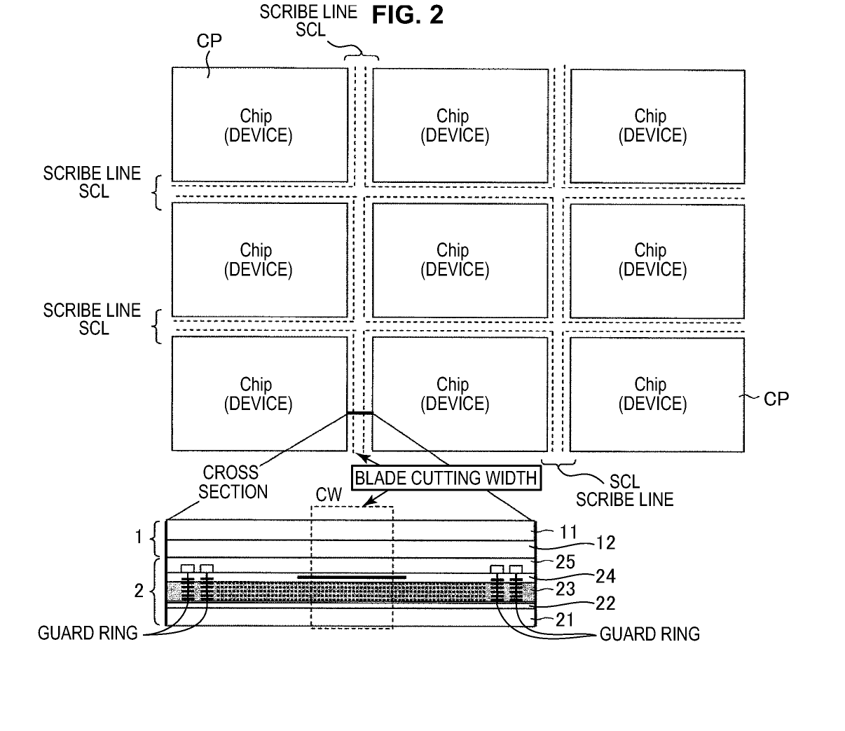

FIGS. 3(A) and 3(B) are diagrams for explaining a problem of blade dicing solely with a blade;

FIG. 4 is a diagram illustrating one example of a layered structure of a solid-state imaging device according to an embodiment;

FIG. 5 is a diagram illustrating an arrangement example of a circuit and the like of the solid-state imaging device having the layered structure of two chips according to the embodiment;

FIG. 6 is a diagram illustrating a process flow of the solid-state imaging device with the layered structure according to the embodiment;

FIG. 7 is a diagram for explaining a manufacturing method and a basic configuration of the solid-state imaging device according to the embodiment which method is of cutting out chips by dicing;

FIGS. 8(A) and 8(B) are diagrams for explaining a first manufacturing method of the solid-state imaging device according to the embodiment;

FIG. 9 is a diagram for explaining a second manufacturing method of the solid-state imaging device according to the embodiment;

FIGS. 10(A) and 10(B) are diagrams for explaining a third manufacturing method of the solid-state imaging device according to the embodiment;

FIG. 11 is a diagram illustrating a basic exemplary configuration of a CMOS image sensor (solid-state imaging device) according to the embodiment;

FIG. 12 is a diagram illustrating one example of a pixel of the CMOS image sensor constituted of four transistors according to the embodiment; and

FIG. 13 is a diagram illustrating one example of a configuration of a camera system to which the solid-state imaging device according to the embodiment is applied.

### DETAILED DESCRIPTION OF THE EMBODIMENT(S)

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted.

Incidentally, the description is made in the following order.

1. Layered Structure of Solid-State Imaging Device 2. Manufacturing Method of Solid-State Imaging Device 2-1. Basic Process Flow 2-2. First Manufacturing Method of Solid-State Imaging Device 2-3. Second Manufacturing Method of Solid-State Imaging Device 2-4. Third Manufacturing Method of Solid-State Imaging Device 3. Summary of Solid-State Imaging Device 4. Exemplary Configuration of Camera System

### <1. Layered Structure of Solid-State Imaging Device>

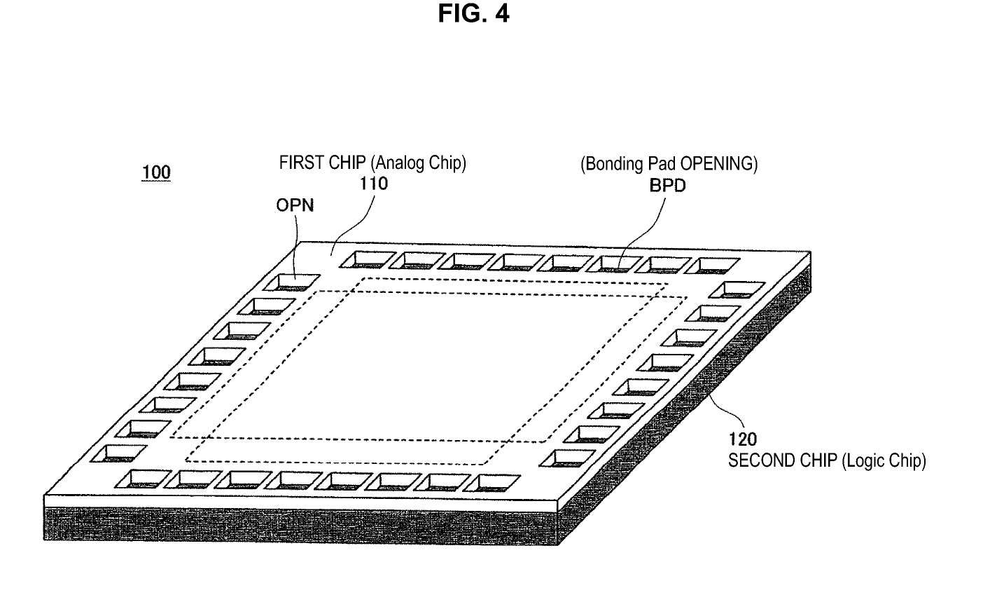

FIG. 4 is a diagram illustrating one example of a layered structure of a solid-state imaging device according to an embodiment. A solid-state imaging device 100 according to the embodiment has a plurality of pixels (sensors) which have photoelectric transducers and the like and are arranged in an array shape.

As illustrated in FIG. 4, the solid-state imaging device 100 has a layered structure of a first chip (upper chip) 110 and a second chip (lower chip) 120. The layered first chip 110 and second chip 120 are electrically connected to each other through via holes (TCV) formed in the first chip 110. This solid-state imaging device 100 is formed as a semiconductor device with a layered structure which device is obtained by cutting due to dicing after wafer-level pasting.

In the layered structure of the upper and lower two chips, the first chip 110 is configured of an analog chip (sensor chip) in which a pixel array including the plurality of pixels in an array shape is disposed. The second chip 120 is configured of a logic chip (digital chip) including a circuit performing quantization on analog signals transferred from the first chip 110 via the TCV and a signal processing circuit (logic circuit). Bonding pads BPD and an input/output circuit are formed in the second chip 120. Openings OPN for wire bonding with the second chip 120 are formed in the first chip 110. Electric connection between the first chip 110 and second chip 120 is realized, for example, through the via holes (TCV). Arrangement positions of the TCV (via holes) are between chip ends or pads (PAD) and a circuit region. For example, TCVs for control signals and power supply are concentrated mainly at four corners of the chip, so that a signal wiring region of the first chip 110 can be reduced. Against the problem that a power supply line resistance increases and IR-Drop increases due to reduction of a wiring layer number of the first chip 110, efficiently arranging the TCV enables measure for noise, enhancement for stable supply and the like as to the power supply of the first chip 110 using wirings of the second chip 120.

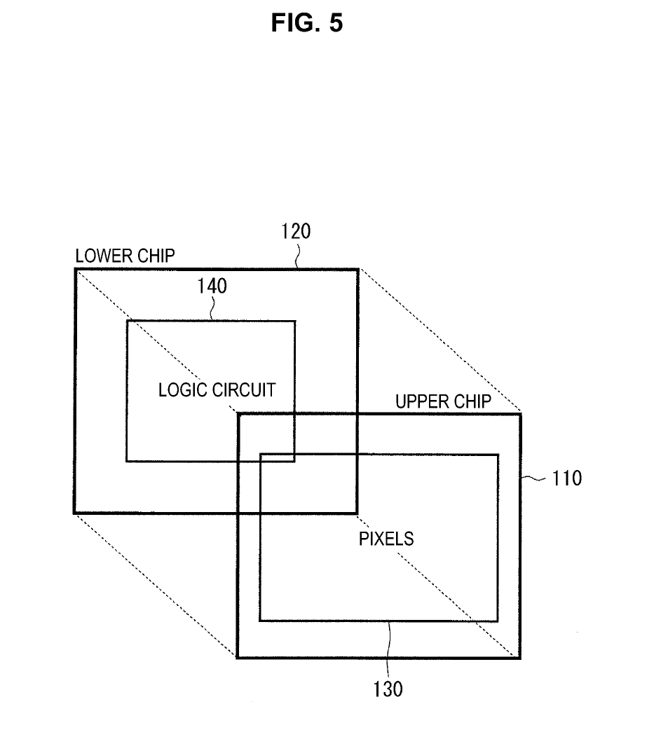

FIG. 5 is a diagram illustrating an arrangement example of a circuit and the like of the solid-state imaging device having the layered structure of two chips according to the embodiment.

As illustrated in FIG. 5, the solid-state imaging device 100 includes a pixel part 130 disposed in the first chip 110 which is an analog chip. The solid-state imaging device 100 has a logic circuit 140, an internal power supply for the logic circuit, and the like, these disposed in the second chip 120 which is a digital chip.

### <2. Manufacturing Method of Solid-State Imaging Device>

Hereinafter, characteristic manufacturing methods and configurations of the solid-state imaging device 100 according to the embodiment having the above-mentioned layered structure are described.

### <2-1. Basic Process Flow>

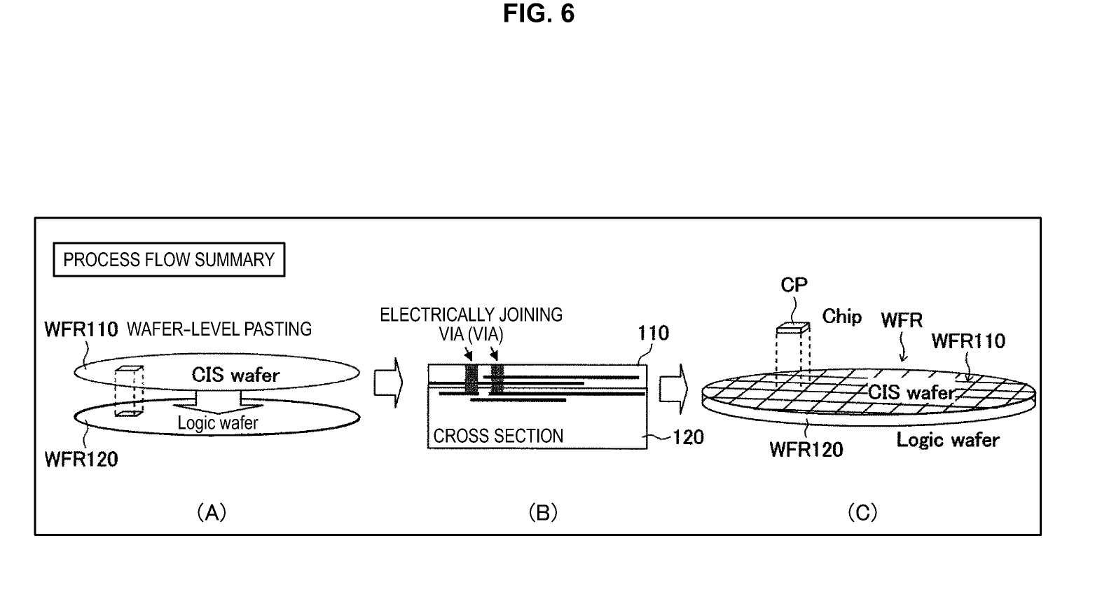

Portions A to C of FIG. 6 illustrate a basic process flow of the solid-state imaging device with the layered structure according to the embodiment.

As illustrated in portion A of FIG. 6, after wafers WFR110 and WFR120 prepared with processes most suitable for the respective upper and lower chips are pasted together, the rear face of the upper chip is polished and the thickness of the wafer of the upper chip is made thinner. After patterning on the first chip (upper chip) 110 side, through holes are bored from the first chip 110 side to a wiring layer of the second chip (lower chip) 120, and they are filled with metal to form via holes (VIA). In the embodiment, this VIA is referred to as TCV. As illustrated in portion B of FIG. 6, this TCV electrically joins signal lines and power supply lines together between the upper and lower chips. Then, as illustrated in portion C of FIG. 6, after performing processing to obtain color filters and microlenses on the first chip (upper chip) 110 side, chips are cut out by dicing.

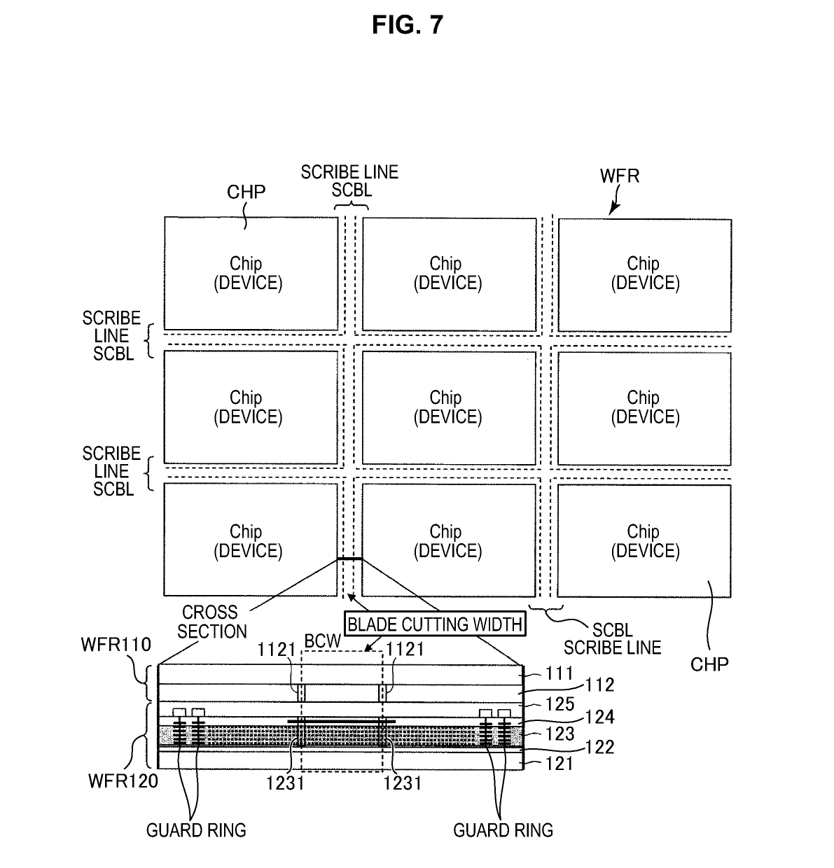

FIG. 7 is a diagram for explaining a manufacturing method, of cutting out chips by dicing, and a basic configuration of the solid-state imaging device according to the embodiment. Moreover, BCW in FIG. 7 denotes a cutting width with a blade.

The wafer with the layered structure in which chips CHP are arranged in an array shape is cut with a blade along scribe lines SCBL indicating positions for cutting between the chips, and is divided into the individual chips CHP.

In FIG. 7, a simplified cross section taken along the scribe line SCBL which is the position for cutting is partially enlarged and illustrated. In the layered structure in FIG. 7, a silicon (Si) layer 111 and a nitride film (for example, SiN film) 112 as a high hardness layer are layered to form the CIS-side wafer WFR110. In practice, sensors and the like are formed on the other face side opposite to the face of the Si layer 111 on which the SiN film is formed. A silicon layer 121, an oxide film 122, a wiring (for example, copper Cu) layer 123 as a low hardness layer, an SiO₂ layer 124 and an SiO₂ layer 125 are layered to form the logic-side wafer WFR120. Furthermore, in the simplified structure in FIG. 7, the SiN film 112 of the CIS-side wafer WFR110 and the SiO₂ layer 125 of the logic-side wafer WFR120 are pasted together.

In addition, the SiN film 112 is a relatively hard film. Moreover, to the wiring layer 123, a low dielectric constant film is applied in order to ensure a low resistance for the reason that such low resistance is not easy to realize due to wirings being thinner while more refinement of the process is being pursued and the like. This wiring layer 123 including the low dielectric constant film is formed of brittle material which is softer in hardness than the other layers, especially, the SiN film 112.

Furthermore, in the manufacturing methods according to the embodiment, this dicing step has a characteristic configuration. In the embodiment, only inside the wiring (low-k) layer 123 with low dielectric constant and the SiN film 112 which is a layer high in hardness (layer in which stress propagating), dividing parts 1121 and 1231 having a predetermined width are beforehand formed with laser or the like. Namely, before performing blade dicing, within boundary regions between the chips CHP and scribe lines SCBL in the wiring layer 123 as a low hardness layer and the SiN film 112 as a high hardness layer, the dividing parts 1121 and 1231 having a predetermined width are formed only inside thereof. Then, positioning is performed such that the cut end face of the blade is located within the width of the dividing parts 1121 and 1231 to perform the blade dicing.

Namely, in the embodiment, before cutting by the blade dicing, the hard film 112 such as a nitride film which is so-called not so sharply cut, the Low-k wiring layer 123 with low dielectric constant, and the like beforehand undergo dividing (breaking). In addition, the hard film is a film with 200 GPa or more of Young's modulus which is a representative value for SiN having already been exemplified, if such hardness is restricted. Thereby, the solid-state imaging device 100 manufactured by the blade dicing is to have the layered structure in which the SiN film 112 and wiring layer 123 have dividing parts (breaking parts) whose structure is different from that of the other layered films. Hereinafter, the manufacturing methods of the solid-state imaging device for selectively forming these dividing parts are described more specifically.

### <2-2. First Manufacturing Method of Solid-State Imaging Device>

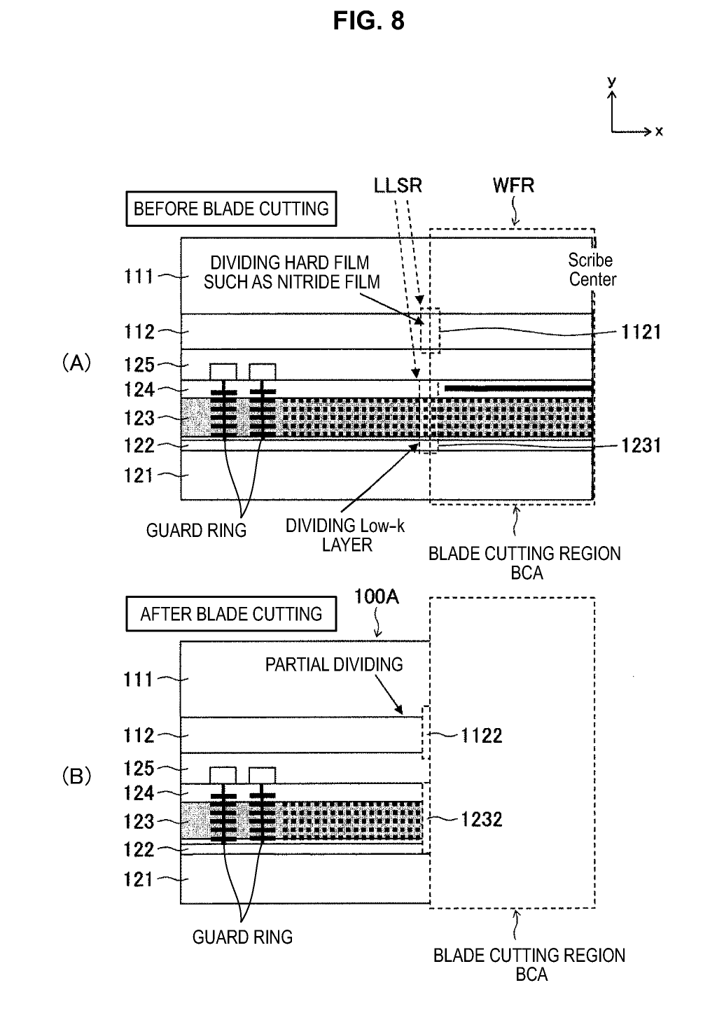

FIGS. 8(A) and 8(B) are diagrams for explaining a first manufacturing method of the solid-state imaging device according to the embodiment.

According to the first manufacturing method, as illustrated in FIG. 8(A), before cutting by blade dicing, the hard film 112 such as a nitride film which is not so sharply cut, the Low-k wiring layer 123 with low dielectric constant, and the like beforehand undergo cutting (breaking). This cutting method employs a laser technique in which pulse-like laser light LLSR is concentrated and focused on the inside of the layered structure body in this first manufacturing method. The laser can include carbon dioxide gas laser, Q switch Nd:YAG laser, eximer laser and the like for use. At this stage, in and in the vicinity of the wiring (low-k) layer 123 with low dielectric constant and the SiN film 112 which is a layer high in hardness (layer in which stress propagating), the dividing parts 1121 and 1231 having a predetermined width are beforehand formed only inside thereof using the laser light LLSR. In this example, the dividing part 1121 is formed in and in the vicinity of the SiN film 112 such that it reaches the silicon layer 111 and SiO₂ layer 125. Similarly, the dividing part 1231 is formed in and in the vicinity of the wiring layer 123 such that it reaches the oxide film 122 and SiO₂ layer 124.

Then, positioning is performed such that the cut end face of the blade is located within the width of the dividing parts 1121 and 1231 to perform the blade dicing. Thereby, a solid-state imaging device 100A manufactured by the blade dicing is to have the layered structure in which the SiN film 112 and wiring layer 123 have dividing parts (breaking parts) 1122 and 1232 whose structure is different from that of the other layered films as illustrated in FIG. 8(B). In this example, the dividing parts (breaking parts) 1122 and 1232 have shapes sinking in an x direction perpendicular to the layering direction y, viewing the section part of the layered structure of the solid-state imaging device 100A.

### <2-3. Second Manufacturing Method of Solid-State Imaging Device>

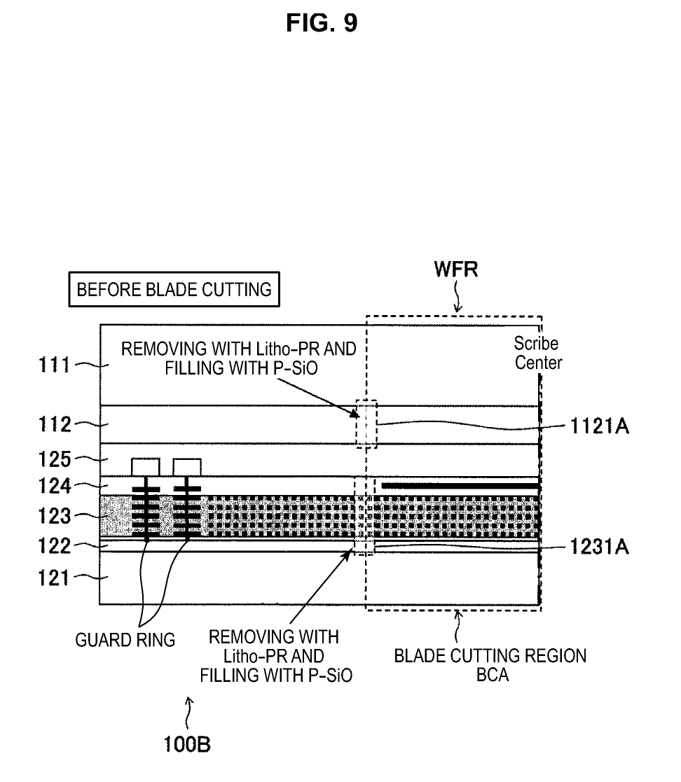

FIG. 9 is a diagram for explaining a second manufacturing method of the solid-state imaging device according to the embodiment.

Difference of the second manufacturing method illustrated in FIG. 9 from the first manufacturing method illustrated in FIG. 8(A) is as follows. In place of the laser technique in which laser light is concentrated and focused on the inside, the second manufacturing method employs a technique in which dividing portions are removed by Litho-PR or the like using lithography technology and are filled with P—SiO or the like. Other steps are performed similarly to those of the first manufacturing method.

### <2-4. Third Manufacturing Method of Solid-State Imaging Device>

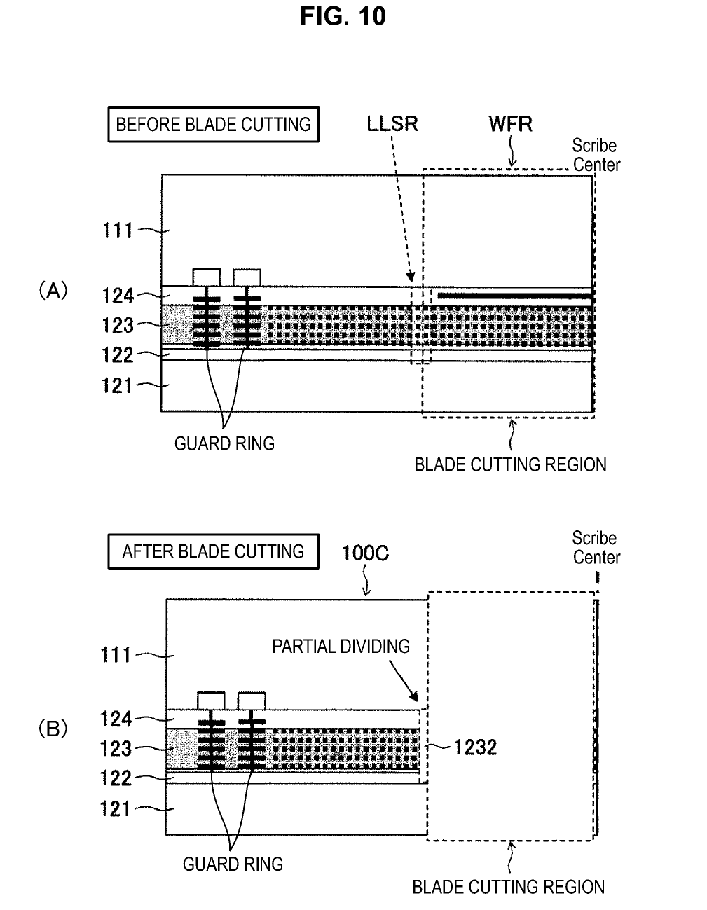

FIGS. 10(A) and 10(B) are diagrams for explaining a third manufacturing method of the solid-state imaging device according to the embodiment.

Difference of the third manufacturing method illustrated in FIGS. 10(A) and 10(B) from the first manufacturing method illustrated in FIGS. 8(A) and 8(B) is as follows. At first, the layered structure is a structure in which a wafer WFR and a solid-state imaging device 100C in FIG. 10 do not have the SiN film 112 which is a layer high in hardness (layer in which stress propagating), and the SiO₂ layer 125. According to this, in and in the vicinity of the wiring (low-k) layer 123 with low dielectric constant, the dividing part 1231 having a predetermined width is beforehand formed only inside thereof using the laser light LLSR. As mentioned above, the dividing part 1231 is formed in and in the vicinity of the wiring layer 123 such that it reaches the oxide film 122 and SiO₂ layer 124.

Then, similarly to the first manufacturing method, positioning is performed such that the cut end face of the blade is located within the width of the dividing part 1231 to perform the blade dicing. Thereby, the solid-state imaging device 100C manufactured by the blade dicing is to have the layered structure in which the wiring layer 123 have a dividing part (breaking part) 1232 whose structure is different from that of the other layered films as illustrated in FIG. 10(B). In this example, the dividing part (breaking part) 1232 has a shape sinking in an x direction perpendicular to the layering direction y, viewing the section part of the layered structure of the solid-state imaging device 100C.

As above, according to the embodiment, only inside the wiring (low-k) layer 123 with low dielectric constant and the nitride film (for example, SiN film) 112 which is a layer high in hardness (layer in which stress propagating), the dividing parts 1121 and 1231 having a predetermined width are beforehand formed using laser or the like. Then, positioning is performed such that the cut end face of the blade is located within the width of the dividing parts 1121 and 1231 to perform the blade dicing. Accordingly, the following effects can be obtained. No dusts arise since the inside of the section due to scribe cutting is irradiated with laser light focusing thereon. Progress of crack can be prevented since layers (Low-k layer and hard layer such as SiN) in which the crack progresses in dicing solely with a blade beforehand undergo dividing. Namely, according to the embodiment, while suppressing occurrence of dusts, occurrence of crack can be prevented even in performing blade dicing. Therefore, cutting quality and yield in dicing can be improved.

### <3. Summary of Solid-State Imaging Device>

An exemplary configuration of a CMOS image sensor is described as one example of the solid-state imaging device according to the embodiment.

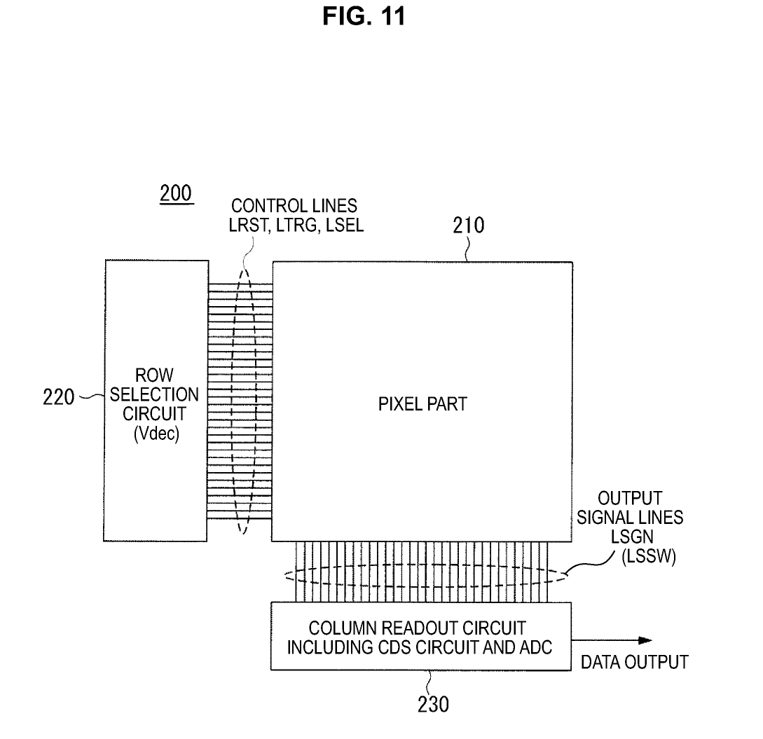

FIG. 11 is a diagram illustrating a basic exemplary configuration of a CMOS image sensor (solid-state imaging device) according to the embodiment.

A CMOS image sensor 200 in FIG. 11 includes a pixel part 210, a row selection circuit (Vdec) 220 and a column readout circuit (AFE) 230. A pixel signal readout part is formed of the row selection circuit 220 and column readout circuit 230.

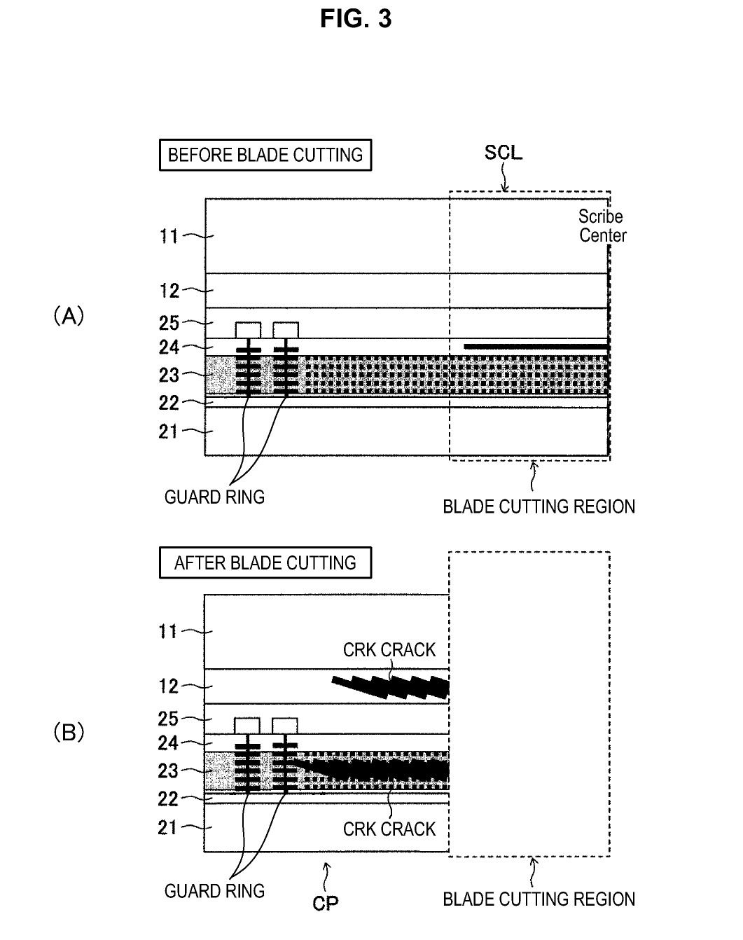

This CMOS image sensor 200 as a semiconductor device employs the layered structure in FIG. 3. In the embodiment, in this layered structure, the pixel part 210 is disposed in the first chip 110, basically. Furthermore, for example, the row selection circuit 220 and column readout circuit 230 which constitute the pixel signal readout part are disposed in the second chip 120. Then, drive signals for pixels, analog readout signals of the pixels (sensors), power supply voltage, and the like are transmitted and received between the first chip 110 and second chip 120 through the TCV formed in the first chip 110.

The pixel part 210 is formed by arranging a plurality of pixel circuits 210A in a two-dimensional shape of M rows×N columns (matrix shape).

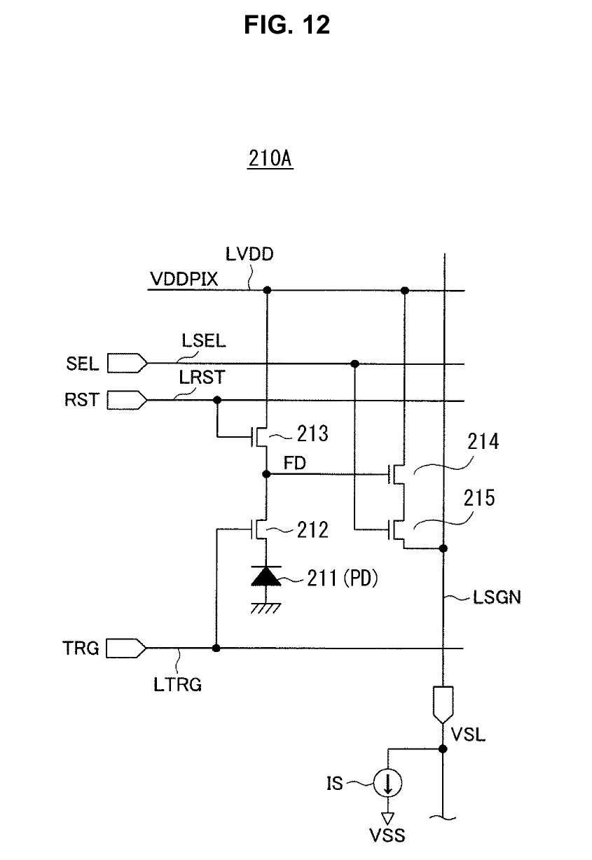

FIG. 12 is a diagram illustrating one example of a pixel of the CMOS image sensor constituted of four transistors according to the embodiment.

This pixel circuit 210A includes a photoelectric transducer (hereinafter, sometimes referred to simply as PD) 211 constituted of a photodiode (PD), for example. Furthermore, the pixel circuit 210A includes four transistors of a transfer transistor 212, a reset transistor 213, an amplification transistor 214 and a selection transistor 215 as active elements with respect to this one photoelectric transducer 211.

The photoelectric transducer 211 performs photoelectric conversion on incident light into charge with an amount (herein, electrons) according to the amount of the light. The transfer transistor 212 as a transfer element is connected between the photoelectric transducer 211 and a floating diffusion FD as an input node, and to its gate (transfer gate), a transfer signal TRG as a control signal is given via a transfer control line LTRG. Thereby, the transfer transistor 212 transfers the electrons obtained by the photoelectric conversion with the photoelectric transducer 211 to the floating diffusion FD.

The reset transistor 213 is connected between a power supply line LVDD through which a power supply voltage VDD is supplied and the floating diffusion FD, and to its gate, a reset signal RST as a control signal is given via a reset control line LRST. Thereby, the reset transistor 213 as a reset element resets a potential of the floating diffusion FD to the potential of the power supply line LVDD.

The gate of the amplification transistor 214 as an amplification element is connected to the floating diffusion FD. Namely, the floating diffusion FD functions as the input node of the amplification transistor 214 as an amplification element. The amplification transistor 214 and selection transistor 215 are connected in series between the power supply line LVDD through which the power supply voltage VDD is supplied and a signal line LSGN. Thus, the amplification transistor 214 is connected to the signal line LSGN via the selection transistor 215, and constitutes a source follower with a constant current source IS outside the pixel part. And a selection signal SEL which is a control signal corresponding to an address signal is given to the gate of the selection transistor 215 via the selection control line LSEL, and the selection transistor 215 is turned on. Upon turning on the selection transistor 215, the amplification transistor 214 amplifies the potential of the floating diffusion FD to output a voltage corresponding to the potential to the signal line LSGN. The voltage outputted from each pixel via the signal line LSGN is outputted to the column readout circuit 230. These operations are performed simultaneously for individual pixels in one row since individual gates, for example, of the transfer transistors 212, reset transistors 213 and selection transistors 215 are connected in row unit.

The reset control line LRST, transfer control line LTRG and selection control line LSEL, which are wired to the pixel part 210, are as one set which undergoes wiring in each row unit of the pixel arrangement. The control lines of each of LRST, LTRG and LSEL provided are M lines for each. These reset control lines LRST, transfer control lines LTRG and selection control lines LSEL are driven by the row selection circuit 220.

The row selection circuit 220 controls operations of pixels arranged in an arbitrary row of the pixel part 210. The row selection circuit 220 controls pixels via the control lines LSEL, LRST and LTRG. The row selection circuit 220 performs image driving control, for example, switching an exposure method between a rolling shutter method of performing exposure for each row and a global shutter method of performing exposure simultaneously for all the pixels according to a shutter mode switching signal

The column readout circuit 230 receives data of the pixel row having undergone readout control performed by the row selection circuit 220 via the signal output line LSGN, and transfers it to the downstream signal processing circuits. The column readout circuit 230 includes a CDS circuit, an ADC (analog digital converter) and the like.

In addition, the CMOS image sensor according to the embodiment is not necessarily limited to but can be a CMOS image sensor mounting a column-parallel analog-digital converter (hereinafter, abbreviated as ADC), for example.

In addition, in the embodiment, the configuration of the CMOS image sensor is described as one example of the semiconductor device, whereas the above-mentioned configuration can be applied, for example, to a back-illuminated CMOS image sensor and can realize the above-mentioned individual effects. However, even in case of a front-illuminated one, the above-mentioned effects can be efficiently realized. The solid-state imaging device having such configuration can be applied as an imaging device for digital cameras, video cameras and the like.

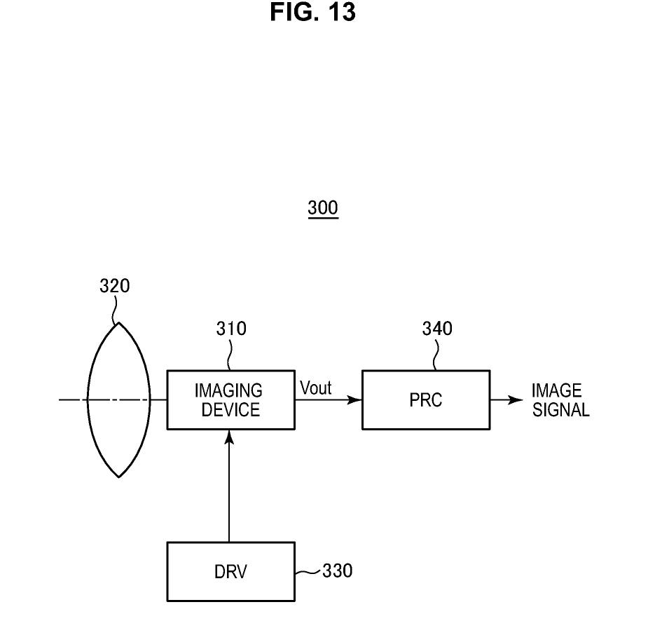

FIG. 13 is a diagram illustrating one example of a configuration of a camera system to which the solid-state imaging device according to the embodiment of the present technology is applied.

As illustrated in FIG. 13, the camera system 300 includes an imaging device 310 to which the CMOS image sensors (solid-state imaging device) 100 and 100A to 100C according to the embodiment can be applied. Furthermore, the camera system 300 includes an optical part guiding incident light to the pixel region of this imaging device 310 (imaging a subject image), for example, a lens 320 imaging incident light (image light) on an imaging plane. The camera system 300 includes a driving circuit (DRV) 330 driving the imaging device 310, and a signal processing circuit (PRC) 340 processing output signals from the imaging device 310.

The driving circuit 330 includes a timing generator (not shown) generating various timing signals including a start pulse, a clock pulse and the like for driving circuits in the imaging device 310, and drives the imaging device 310 with predetermined timing signals.

Moreover, the signal processing circuits 340 performs predetermined signal processing on the output signals from the imaging device 310. The image signal processed by the signal processing circuit 340 is recorded in a recording medium such, for example, as a memory. The image information recorded in the recording medium undergoes hard-copy with a printer or the like. Moreover, the image signal processed by the signal processing circuit 340 is displayed as a moving image on a monitor constituted of a liquid crystal display and the like.

As described above, any of the previously mentioned image sensors 100 and 100A to 100C is mounted as the imaging device 310 in an image capturing device such as a digital still camera, and thereby, a camera high in accuracy and reliability can be realized.

Additionally, the present technology may also be configured as below.

(1) A solid-state imaging device including:

a pixel part obtained by arranging a plurality of pixels performing photoelectric conversion; and

a pixel signal readout part including a logic part and reading out a pixel signal from the pixel part,

wherein the pixel part and the logic part are formed as a layered structure,

wherein the layered structure includes a low hardness layer at least lower in hardness than another layer out of a plurality of layers, and

wherein a dividing part different from the other layer is formed in a side portion of the low hardness layer.

(2) The solid-state imaging device according to (1),

wherein a high hardness layer higher in hardness than the low hardness layer is included above the low hardness layer in the layered structure, and

wherein a dividing part different from the other layer is formed in a side portion of the high hardness layer.

(3) The solid-state imaging device according to (1) or (2),

wherein the low hardness layer includes a wiring layer with low dielectric constant.

(4) The solid-state imaging device according to any one of (1) to (3), including:

a first chip; and

a second chip,

wherein the first chip and the second chip have the layered structure obtained by pasting the chips together,

wherein the pixel part is disposed in the first chip, and

wherein at least the logic part is disposed in the second chip.

(5) A manufacturing method of a solid-state imaging device, including:

in performing blade dicing along a scribe line between chips with respect to a wafer obtained by arranging, in an array shape, the chips each having a layered structure which is obtained by layering a pixel part obtained by arranging a plurality of pixels performing photoelectric conversion and a logic part and includes a low hardness layer at least lower in hardness than another layer out of a plurality of layers,

before performing the blade dicing, forming a dividing part, for dividing, having a predetermined width only inside at least within a boundary region between the chip and the scribe line in the low hardness layer; and

after that, performing positioning such that a cut end face of a blade is located within the width of the dividing part to perform the blade dicing.

(6) The manufacturing method of a solid-state imaging device according to (5),

wherein a high hardness layer higher in hardness than the low hardness layer is included above the low hardness layer in the layered structure, and

wherein, before performing the blade dicing, a dividing part having a predetermined width only inside is formed also within a boundary region between the chip and the scribe line in the high hardness layer.

(7) The manufacturing method of a solid-state imaging device according to (5) or (6),

wherein the dividing part is formed by concentrating and focusing laser light on a predetermined portion inside.

(8) The manufacturing method of a solid-state imaging device according to (5) or (6),

wherein the dividing part is formed by a dividing portion beforehand removed and filled with a predetermined film.

(9) The manufacturing method of a solid-state imaging device according to any one of (5) to (8),

wherein the low hardness layer includes a wiring layer with low dielectric constant.

(10) The manufacturing method of a solid-state imaging device according to any one of (5) to (9),

wherein the wafer is formed as a layered structure obtained by pasting a first wafer in which a plurality of first chips are formed and a second wafer in which a plurality of second chips are formed together,

wherein the pixel part is disposed in the first chip, and

wherein at least the logic part is disposed in the second chip.

(11) A camera system including:

a solid-state imaging device; and

an optical part imaging a subject image in the solid-state imaging device,

wherein the solid-state imaging device includes
a pixel part obtained by arranging a plurality of pixels performing photoelectric conversion, and
a pixel signal readout part including a logic part and reading out a pixel signal from the pixel part,

wherein the pixel part and the logic part are formed as a layered structure,

wherein the layered structure includes a low hardness layer at least lower in hardness than another layer out of a plurality of layers, and

wherein a dividing part different from the other layer is formed in a side portion of the low hardness layer.

It should be understood by those skilled in the art that various modifications, combinations, sub-combinations and alterations may occur depending on design requirements and other factors insofar as they are within the scope of the appended claims or the equivalents thereof.

The present disclosure contains subject matter related to that disclosed in Japanese Priority Patent Application JP 2012-035311 filed in the Japan Patent Office on Feb. 21, 2012, the entire content of which is hereby incorporated by reference.

What is claimed is:

1. A solid-state imaging device comprising:
a pixel part obtained by arranging a plurality of pixels performing photoelectric conversion; and
a pixel signal readout part including a logic part and reading out a pixel signal from the pixel part,
wherein the pixel part and the logic part are formed as a layered structure,
wherein the layered structure includes a low hardness layer at least lower in hardness than another layer out of a plurality of layers, and
wherein a dividing part different from the other layer is formed in a side portion of the low hardness layer.

2. The solid-state imaging device according to claim 1,
wherein a high hardness layer higher in hardness than the low hardness layer is included above the low hardness layer in the layered structure, and
wherein a dividing part different from the other layer is formed in a side portion of the high hardness layer.

3. The solid-state imaging device according to claim 1,
wherein the low hardness layer includes a wiring layer with low dielectric constant.

4. The solid-state imaging device according to claim 1, comprising:
a first chip; and
a second chip,
wherein the first chip and the second chip have the layered structure obtained by pasting the chips together,
wherein the pixel part is disposed in the first chip, and
wherein at least the logic part is disposed in the second chip.

5. A manufacturing method of a solid-state imaging device, comprising:
in performing blade dicing along a scribe line between chips with respect to a wafer obtained by arranging, in an array shape, the chips each having a layered structure which is obtained by layering a pixel part obtained by arranging a plurality of pixels performing photoelectric conversion and a logic part and includes a low hardness layer at least lower in hardness than another layer out of a plurality of layers,
before performing the blade dicing, forming a dividing part, for dividing, having a predetermined width only inside at least within a boundary region between the chip and the scribe line in the low hardness layer; and
after that, performing positioning such that a cut end face of a blade is located within the width of the dividing part to perform the blade dicing.

6. The manufacturing method of a solid-state imaging device according to claim 5,
wherein a high hardness layer higher in hardness than the low hardness layer is included above the low hardness layer in the layered structure, and
wherein, before performing the blade dicing, a dividing part having a predetermined width only inside is formed also within a boundary region between the chip and the scribe line in the high hardness layer.

7. The manufacturing method of a solid-state imaging device according to claim 5,
wherein the dividing part is formed by concentrating and focusing laser light on a predetermined portion inside.

8. The manufacturing method of a solid-state imaging device according to claim 5,
wherein the dividing part is formed by a dividing portion beforehand removed and filled with a predetermined film.

9. The manufacturing method of a solid-state imaging device according to claim 5,
wherein the low hardness layer includes a wiring layer with low dielectric constant.

10. The manufacturing method of a solid-state imaging device according to claim 5,
wherein the wafer is formed as a layered structure obtained by pasting a first wafer in which a plurality of first chips are formed and a second wafer in which a plurality of second chips are formed together,
wherein the pixel part is disposed in the first chip, and
wherein at least the logic part is disposed in the second chip.

11. A camera system comprising:
a solid-state imaging device; and
an optical part imaging a subject image in the solid-state imaging device,
wherein the solid-state imaging device includes
a pixel part obtained by arranging a plurality of pixels performing photoelectric conversion, and
a pixel signal readout part including a logic part and reading out a pixel signal from the pixel part,
wherein the pixel part and the logic part are formed as a layered structure,
wherein the layered structure includes a low hardness layer at least lower in hardness than another layer out of a plurality of layers, and
wherein a dividing part different from the other layer is formed in a side portion of the low hardness layer.
